(19) United States
(12) Patent Application Publication
(10) Pub. No.: US 2026/0282704 A1
(43) Pub. Date: Sep. 17, 2026

(54) DISPLAY PANEL AND MANUFACTURING METHOD THEREFOR, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Shilong WANG, Beijing (CN); Zhiliang JIANG, Beijing (CN); Ming HU, Beijing (CN); Haijun QIU, Beijing (CN); Ge NIU, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 19/473,506

(22) PCT Filed: Jun. 17, 2024
(86) PCT No.: PCT/CN2024/099591

§ 371 Date: Oct. 8, 2025

(30) Foreign Application Priority Data
Jul. 27, 2023 (CN) 202310931110.9

(51) Int. Cl. H10K 59/80; H10K 59/12

(52) U.S. Cl. CPC H10K 59/80521; H10K 59/1201

(57) ABSTRACT

The present disclosure relates to a display panel, including: an array substrate; and a light-emitting layer located on a side of the array substrate and including a plurality of light-emitting units, wherein each light-emitting unit includes an anode block, a light-emitting functional layer, and a cathode block stacked in sequence in a direction away from the array substrate; wherein the light-emitting layer includes a cathode layer, and the cathode layer includes a plurality of cathode blocks distributed at intervals.

### CROSS-REFERENCE TO RELATED APPLICATIONS

The present application is a U.S. National Stage Application of International Application No. PCT/CN2024/099591, filed on Jun. 17, 2024, which is based upon and claims the priority to the Chinese Patent Application NO. 202310931110.9, entitled “DISPLAY PANEL AND MANUFACTURING METHOD THEREOF, AND DISPLAY DEVICE”, filed on Jul. 27, 2023, the entire contents of each are hereby incorporated by reference.

### TECHNICAL FIELD

The present disclosure relates to the field of display technologies, and in particular, to a display panel and a manufacturing method thereof, and a display device.

### BACKGROUND

Display panels have been widely used in electronic devices such as mobile phones, computers and televisions, and with the rapid development of the display panels, users have increasingly higher requirements for the image display of the display panels, such as the brightness of the displayed image.

It should be noted that the information disclosed in the Background section above is only for enhancing the understanding of the background of the present disclosure, and thus may include information that does not constitute prior art known to those of ordinary skill in the art.

### SUMMARY

According to an aspect of the present disclosure, there is provided a display panel, including:
an array substrate; and
a light-emitting layer located on a side of the array substrate and including a plurality of light-emitting units, wherein each light-emitting unit includes an anode block, a light-emitting functional layer, and a cathode block stacked in sequence in a direction away from the array substrate;
wherein the light-emitting layer includes a cathode layer, and the cathode layer includes a plurality of cathode blocks distributed at intervals.

According to an aspect of the present disclosure, there is provided a method for manufacturing a display panel, and the method includes:
manufacturing an array substrate; and
manufacturing a light-emitting layer on a side of the array substrate, wherein the light-emitting layer includes a plurality of light-emitting units, the light-emitting unit includes an anode block, a light-emitting functional layer, and a cathode block stacked in sequence in a direction away from the array substrate, the light-emitting layer includes a cathode layer, and the cathode layer includes a plurality of cathode blocks distributed at intervals.

According to an aspect of the present disclosure, there is provided a display device, including the display panel described in the above aspect.

It should be noted that the above general description and the following detailed description are merely exemplary and explanatory and should not be construed as limiting of the disclosure.

### BRIEF DESCRIPTION OF THE DRAWINGS

The drawings herein are incorporated in and constitute a part of the specification, illustrate embodiments consistent with the present disclosure, and together with the description serve to explain principles of the present disclosure. Apparently, the drawings in the following description are only some embodiments of the present disclosure. For those of ordinary skill in the art, other drawings may be obtained based on these drawings without paying any creative effort.

FIG. 1 is a schematic cross-sectional structure view of a display panel provided by an embodiment of the present disclosure.

FIG. 2 is a schematic cross-sectional structure view of another display panel provided by an embodiment of the present disclosure.

FIG. 3 is a schematic cross-sectional structure view of another display panel provided by an embodiment of the present disclosure.

FIG. 4 is a schematic top structure view of a display panel provided by an embodiment of the present disclosure.

FIG. 5 is a schematic cross-sectional structure view of yet another display panel provided by an embodiment of the present disclosure.

FIG. 6 is a schematic cross-sectional structure view of still another display panel provided by an embodiment of the present disclosure.

FIG. 7 is a schematic flowchart of manufacturing a display panel provided by an embodiment of the present disclosure.

Reference numerals:
100. display panel;
10. array substrate; 20. light-emitting layer; 30. voltage signal line;
11. base substrate; 12. driving layer;
121. buffer layer; 122. semiconductor layer; 123. gate insulation layer; 124. gate metal layer; 125. interlayer dielectric layer; 126. source-drain metal layer; 127. planarization layer;

21. anode layer; 22. organic light-emitting layer; 23. cathode layer; 24. pixel definition layer; 25. transfer portion;

211. anode block; 212. anode transfer block;

221. light-emitting functional layer; 222. light-emitting transfer block; 223. partition portion;

231. cathode block; and
241. pixel opening; 242. transfer opening.

### DETAILED DESCRIPTION

Example embodiments will now be described more fully with reference to the accompanying drawings. However, the example embodiments can be implemented in a variety of forms and should not be construed as being limited to the embodiments set forth herein; rather, these embodiments are provided so that the present disclosure will be more complete and comprehensive so as to convey the idea of the example embodiments to those skilled in this art. The same reference numerals in the drawings denote the same or similar structures, and the repeated description thereof will be omitted. In addition, the drawings are merely schematic representations of the present disclosure and are not necessarily drawn to scale.

Although the relative terms such as “above” and “below” are used in the specification to describe the relative relationship of one component to another component shown, these terms are only for convenience in this specification, for example, according to an example direction shown in the drawings. It will be understood that if the device shown is flipped upside down, the component described as “above” will become a component “below” another component. When a structure is “on” another structure, it may mean that a structure is integrally formed on another structure, or that a structure is “directly” disposed on another structure, or that a structure is “indirectly” disposed on another structure through other structures.

The terms “one”, “a”, “the”, “said”, and “at least one” are used to indicate that there are one or more elements/components or the like; the terms “include” and “have” are used to indicate an open meaning of including and means that there may be additional elements/components/etc. in addition to the listed elements/components/etc. ; the terms “first”, “second” and “third” etc. are used only as markers, and do not limit the number of objects.

In the present disclosure, a transistor refers to an element including at least three terminals, i.e., a gate, a drain, and a source. The transistor has a channel region between the drain (drain terminal, drain region or drain electrode) and the source (source terminal, source region or source electrode), and the current flows through the drain, the channel region and the source. The channel region refers to a region through which the current mainly flows. The functions of “source” and “drain” may be interchanged with each other when transistors of an opposite type are used or when the direction of the current changes during circuit operation. Therefore, in the present disclosure, “source” and “drain” may be interchanged with each other. Structurally, the transistor may have a first terminal, a second terminal and a control terminal. The gate of the transistor may be used as the control terminal (or control electrode) of the transistor. One of the source and the drain of the transistor may be used as the first terminal of the transistor, and the other of the source and the drain of the transistor may be used as the second terminal of the transistor.

In the present disclosure, the “on” state of the transistor refers to a state in which the source and the drain of the transistor are electrically connected. The “off” state of the transistor refers to a state in which the source and the drain of the transistor are electrically disconnected. It can be understood that when the transistor is turned off, leakage current may still exist.

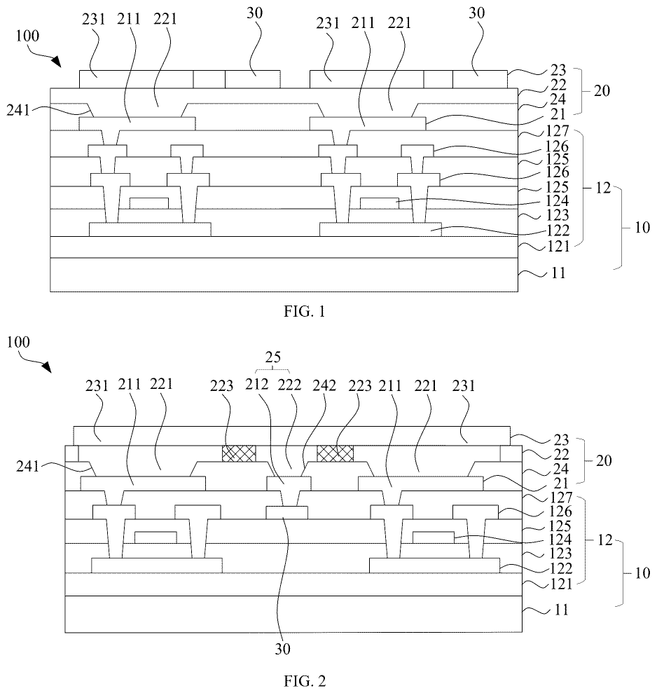

Embodiments of the present disclosure provide a display panel 100. As shown in FIG. 1, the display panel 100 includes an array substrate 10 and a light-emitting layer 20. The array substrate 10 is formed with a plurality of pixel circuits. The light-emitting layer 20 is located on a side of the array substrate 10 and includes a plurality of light-emitting units. A pixel circuit is connected to at least one corresponding light-emitting unit (for example, one pixel circuit is connected to one corresponding light-emitting unit). In this way, the corresponding light-emitting unit is driven to emit light by the pixel circuit, thereby achieving the display of the image.

The plurality of pixel circuits on the array substrate 10 can be distributed in an array, which can be 1T1C, 2T1C, 7T1C, or other circuits, as long as they can drive at least one corresponding light-emitting unit to emit light, which are not specifically limited in embodiments of the present disclosure. nTmC indicates that a pixel circuit includes n transistors (represented by the letter “T”) and m capacitors Cst (represented by the letter “C”).

The capacitor Cst included in the pixel circuit can be a storage capacitor, a parasitic capacitor, or the like. Alternatively, each pixel circuit can further include both the storage capacitor and the parasitic capacitor. For capacitors Cst of the same type included in the plurality of pixel circuits, areas of their projections in a thickness direction of the array substrate 10 are equal (“equal” here refers to theoretical equality and does not limit errors caused by the manufacturing process). In this way, it is ensured that electrical parameters of individual pixel circuits are the same, thereby ensuring that the light-emitting units corresponding to individual pixel circuits have the same luminous effect when emitting light.

As shown in FIG. 1, the array substrate 10 includes a transparent base substrate 11 and a driving layer 12 located on a side of the base substrate 11, or includes a silicon substrate and a wiring layer located on a side of the silicon substrate.

Taking the array substrate 10 including the base substrate 11 and the driving layer 12 as an example, the base substrate 11 can be, for example, a glass substrate, a quartz substrate, a plastic substrate, or other transparent rigid or flexible substrate, and can be a single-layer or multi-layer structure. Taking the multi-layer structure as an example, the base substrate 11 includes a first polyimide (PI) layer, a first protective layer, a second polyimide (PI) layer, and a second protective layer stacked in sequence from bottom to top. These two protective layers are used to protect the PI layers from being damaged by the subsequent processes. The second protective layer is also covered with a buffer layer 121 to block water, oxygen, and alkaline ions.

As shown in FIG. 1, the driving layer 12 includes the buffer layer 121, a transistor layer, an interlayer dielectric layer 125, a source-drain metal layer 126, and a planarization layer 127, which are sequentially distributed in a direction away from the base substrate 11. The transistor layer includes a semiconductor layer 122, a gate insulation layer 123, and a gate metal layer 124, which are stacked between the buffer layer 121 and the interlayer dielectric layer 125. A positional relationship of various film layers included in the transistor layer can be determined based on the film layer structure of the thin film transistor.

A material of the buffer layer 121 can be an inorganic insulating material such as silicon oxide or silicon nitride. The buffer layer 121 can be a single inorganic material layer or a multi-layered inorganic material layer. The semiconductor layer 122 can be used to form active portions of individual transistors included in the pixel circuit. Each active portion includes a channel region and two connection portions (i.e., the source and drain of the transistor) located on both sides of the channel region. The channel region can maintain semiconductor properties, and semiconductor materials corresponding to the two connection portions are partially or completely conductive. The gate metal layer 124 can be used to form a scan line (the scan line forms the gate of the transistor in an area overlapping with the channel region of the active portion) and other wirings, and can also be used to form a second electrode plate of the storage capacitor. The source-drain metal layer 126 can be used to form wirings of the source-drain metal layer 126 such as power lines, data lines, sensing lines, and connection lines, and can also be used to form a first electrode plate of the storage capacitor.

In some embodiments, the semiconductor layer 122 may be one semiconductor layer 122 or two semiconductor layers 122. For example, the semiconductor layer 122 includes a low-temperature polysilicon semiconductor layer 122. The gate metal layer 124 may be one gate metal layer 124, two gate metal layers 124 or three gate metal layers 124. For example, the gate metal layer 124 includes one gate metal layer 124.

It can be understood that when the gate metal layer 124, the semiconductor layer 122 or the like has a multi-layer structure, the gate insulation layer 123 in the transistor layer can be adaptively increased or decreased. For example, the driving layer 12 includes the low-temperature polysilicon semiconductor layer 122, the gate insulation layer 123, and the gate metal layer 124 stacked in sequence on the base substrate 11.

In some embodiments, the source-drain metal layer 126 may be one source-drain metal layer 126, or may be two or three source-drain metal layers 126. For example, as shown in FIG. 2, the driving layer 12 includes one source-drain metal layer 126, and as shown in FIG. 1, the driving layer 12 includes two source-drain metal layers 126. In the case of the plurality of source-drain metal layers 126, a passivation layer and/or a planarization layer 127 is provided between two adjacent source-drain metal layers 126 to achieve insulation between the two adjacent source-drain metal layers 126 via the passivation layer and/or the planarization layer 127.

In some embodiments, the light-emitting unit may be an organic light-emitting diode, a micro light-emitting diode, a quantum dot-organic light-emitting diode, a quantum dot light-emitting diode, or other types of light-emitting units.

For example, in some embodiments, the light-emitting unit is the organic light emitting diode, and the display panel 100 is an OLED display panel 100. In the following, taking the light-emitting unit as the organic light emitting diode as an example, a feasible structure of the light-emitting unit is illustratively introduced.

As shown in FIG. 1 or FIG. 2, the light-emitting unit includes an anode block 211, a light-emitting functional layer 221 and a cathode block 231 stacked in sequence in a direction away from the array substrate 10. The light-emitting functional layer 221 may include an organic electroluminescent material layer, and may further include one or more of a hole injection layer, a hole transport layer, an electron blocking layer, a hole blocking layer, an electron transport layer and an electron injection layer.

In addition, as shown in FIG. 1 or FIG. 2, the light-emitting layer 20 further includes a pixel definition layer 24 disposed on a side of the driving layer 12 away from the base substrate 11. The pixel definition layer 24 is provided with pixel openings 241 in a one-to-one correspondence with the plurality of light-emitting units. Each light-emitting unit is located in the corresponding pixel opening 241, and the anode block 211 includes an exposed area exposed at the corresponding pixel opening 241 and an area covered by the pixel definition layer 24. The exposed area of the anode block 211 forms a light-emitting area of the corresponding light-emitting unit.

In some embodiments, the display panel 100 may further include a thin film encapsulation layer disposed on a side of the light-emitting layer 20 away from the array substrate 11. The thin film encapsulation layer may include inorganic encapsulation layers and organic encapsulation layers alternately stacked.

The inorganic encapsulation layer can effectively block external moisture and oxygen, preventing water and oxygen from invading the organic light-emitting functional layer 221 to cause the material degradation. The organic encapsulation layer is located between two adjacent inorganic encapsulation layers to achieve planarization and reduce the stress between the inorganic encapsulation layers.

The display panel 100 includes a display area and a peripheral area located outside the display area. An edge of the inorganic encapsulation layer may be located in the peripheral area, and an edge of the organic encapsulation layer may be located between an edge of the display area and the edge of the inorganic encapsulation layer. For example, the thin film encapsulation layer includes a first inorganic encapsulation layer, an organic encapsulation layer, and a second inorganic encapsulation layer sequentially stacked on the side of the light-emitting layer 20 away from the array substrate 11.

In some embodiments, the display panel 100 may further include a touch functional layer disposed on a side of the thin film encapsulation layer away from the array substrate 11 and used to implement a touch operation of the display panel 100.

In embodiments of the present disclosure, as shown in FIG. 1 or FIG. 2, the light-emitting layer 20 includes an anode layer 21, an organic light-emitting layer 22 and a cathode layer 23 stacked in the direction away from the array substrate 10. The anode layer 21 includes anode blocks 211 of the plurality of light-emitting units, the organic light-emitting layer 22 includes light-emitting functional layers 221 of the plurality of light-emitting units, and the cathode layer 23 includes cathode blocks 231 of the plurality of light-emitting units.

As shown in FIG. 1 or FIG. 2, a plurality of cathode blocks 231 included in the cathode layer 23 are distributed at intervals, thereby reducing the occlusion of brightness by the cathode layer 23 in areas outside the light-emitting unit, thereby further increasing the brightness of the display panel 100 when displaying an image and improving the display effect.

The display panel 100 includes a voltage signal line 30 for loading a voltage signal (i.e., a VSS signal) onto the cathode block 231 via the voltage signal line 30. For the plurality of cathode blocks 231 included in the cathode layer 23, when an image is displayed, a voltage signal can be loaded onto each cathode block 231 individually. In this case, the display panel 100 includes a plurality of voltage signal lines 30 in a one-to-one correspondence with the plurality of cathode blocks 231, thereby loading voltage signals onto the plurality of cathode blocks 231 via the plurality of voltage signal lines 30, respectively. Alternatively, the voltage signal can also be loaded to some of the plurality of cathode blocks 231 which are configured as an integrated structure. In this case, the display panel 100 includes a plurality of voltage signal lines 30, and each voltage signal line 30 corresponds to a plurality of cathode blocks 231 which are configured as the integrated structure, thereby loading, via one voltage signal line 30, the voltage signal onto the plurality of cathode blocks 231 configured as the integrated structure.

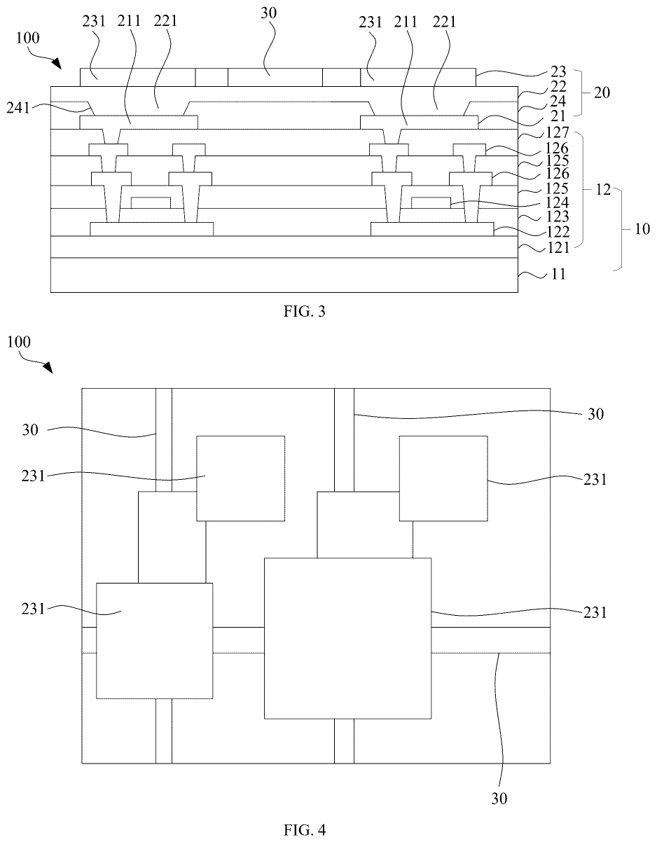

For the plurality of cathode blocks 231 configured as the integrated structure, as shown in FIGS. 3 and 4, the cathode layer 23 includes a plurality of groups of cathode blocks 231, each group of cathode blocks 231 being an integrated structure. Thus, the plurality of cathode blocks 231 included in the cathode layer 23 are divided into a plurality of groups, so as to reduce the number of voltage signal lines 30 loading the voltage signals, thereby simplifying the structure of the display panel 100 and simplifying the manufacturing process.

The plurality of groups of cathode blocks 231 in the cathode layer 23 can be manufactured through a fine mask plate, and the plurality of cathode blocks 231 included in each group can be integrated into an integrated structure through connection strips, so as to reduce the obstruction of brightness through the narrower connection strips and ensure the brightness of the display panel 100 when displaying the image.

The number of cathode blocks 231 included in each group may be the same, different, or not all the same. For example, if the number of cathode blocks 231 included in each group is the same, as shown in FIG. 3 or FIG. 4, each group of cathode blocks 231 includes two cathode blocks 231. For example, if the number of cathode blocks 231 included in each group is not all the same, some of the plurality of groups of cathode blocks 231 include two cathode blocks 231, and the remaining groups include three cathode blocks 231.

In embodiments of the present disclosure, for the voltage signal line 30 that loads the voltage signal onto the cathode block 231, in conjunction with the case of the display panel 100 including the array substrate 10 and the light-emitting layer 20, the voltage signal line 30 can be formed on the array substrate 10, or on the light-emitting layer 20. Alternatively, the voltage signal lines 30 can also be formed on both the array substrate 10 and the light-emitting layer 20.

In some embodiments, the voltage signal line 30 is formed on the light-emitting layer 20, that is, the light-emitting layer 20 includes the voltage signal line 30, and the voltage signal line 30 is connected to the cathode block 231.

In conjunction with the case of the light-emitting layer 20 including the anode layer 21, the organic light-emitting layer 22, and the cathode layer 23, the voltage signal line 30 can be formed on the anode layer 21, or can be formed on the cathode layer 23. Alternatively, to avoid increased process difficulty due to a large number of voltage signal lines 30 when the voltage signal lines 30 are provided in a single layer, the voltage signal lines 30 can be formed on both the anode layer 21 and the cathode layer 23, which are not limited by embodiments of the present disclosure.

When the anode layer 21 is formed with the voltage signal line 30, the voltage signal line 30 extends in an area outside the anode block 211 and is spaced apart from the anode block 211 to avoid crosstalk between the anode block 211 and the voltage signal line 30. In conjunction with the case where the light-emitting layer 20 includes the pixel definition layer 24, the pixel definition layer 24 has, in addition to the pixel opening 241, a transfer opening 242 (there is no overlap between the transfer opening 242 and the pixel opening 241). After the pixel definition layer 24 covers the voltage signal line 30, the voltage signal line 30 is exposed at the transfer opening 242, and the exposed portion of the voltage signal line 30 at the transfer opening 242 is used to be connected to the cathode block 231.

When the voltage signal line 30 is connected to the cathode block 231 at the transfer opening 242, if the plurality of light-emitting functional layers 221 included in the organic light-emitting layer 22 form an integrated structure as a whole layer, the voltage signal line 30 can be connected to the cathode block 231 through the organic light-emitting layer 22. In this case, although leakage current will be generated between the voltage signal line 30 and the adjacent anode block 211 due to the presence of the organic light-emitting layer 22, the resistivity of the organic light-emitting layer 22 in a direction perpendicular to the display panel 100 is more than 20 times the resistivity of the anode block 211, and the resistivity of the organic light-emitting layer 22 is even greater within the plane of the display panel 100, and thus the leakage current generated by the organic light-emitting layer 22 can be ignored, ensuring the voltage signal loaded on the cathode block 231 by the voltage signal line 30.

If the plurality of light-emitting functional layers 221 included in the organic light-emitting layer 22 are distributed at intervals, the transfer opening 242 on the pixel definition layer 24 is located in an area outside the pixel opening 241, thereby ensuring that the cathode block 231 is directly connected, at the transfer opening 242, to the voltage signal line 30 on the anode layer 21, while avoiding the generation of the leakage current between the voltage signal line 30 and the anode block 211.

When the cathode layer 23 is formed with the voltage signal line 30, as shown in FIG. 1 or FIG. 3, the voltage signal line 30 is located outside the cathode block 231. The voltage signal line 30 and the cathode block 231 can be connected by a connection block or can be an integral structure, which is not limited in embodiments of the present disclosure.

It should be noted that, compared with the case where the voltage signal line 30 is formed in the cathode layer 23, when the voltage signal line 30 is formed in the anode layer 21, whether the voltage signal line 30 is light-transmissive will not affect the brightness of the display panel 100, thereby facilitating the use of a metal material with a lower resistivity to make the voltage signal line 30, so as to reduce the voltage drop when the voltage signal is loaded on the cathode block 231, thereby reducing power consumption.

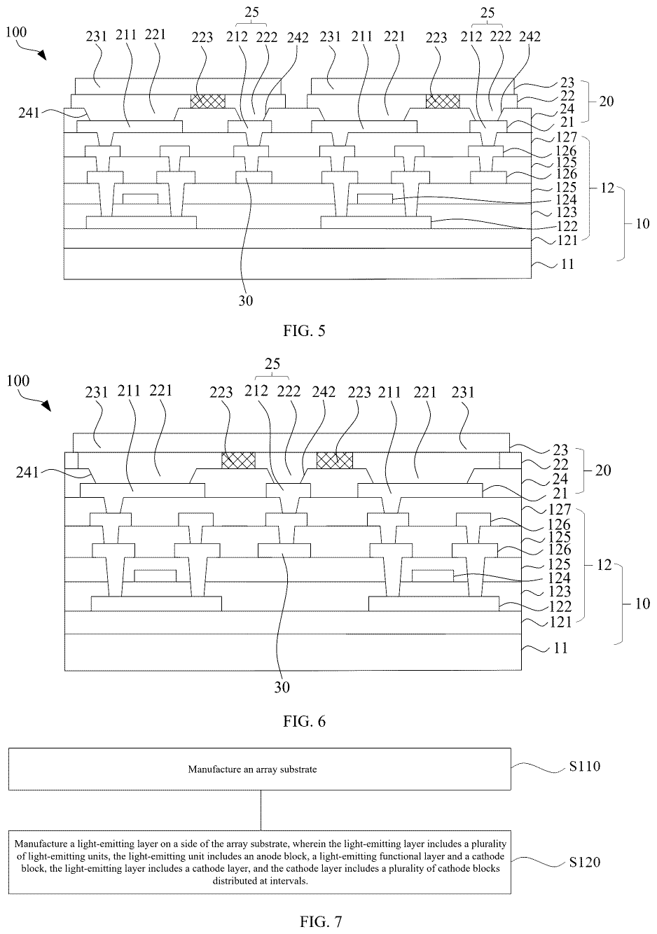

In some other embodiments, as shown in FIG. 2 or FIG. 5, the voltage signal line 30 is formed on the array substrate 10, that is, the array substrate 10 includes the voltage signal line 30. In this case, the light-emitting layer 20 further includes a transfer portion 25, which is respectively connected to the voltage signal line 30 and the cathode block 231. In this way, since whether the voltage signal line 30 is light-transmissive does not affect the brightness of the display panel 100, it is convenient to use a metal material with a low resistivity to make the voltage signal line 30, thereby reducing the voltage drop when the voltage signal is loaded on the cathode block 231, thereby reducing power consumption.

For the voltage signal line 30 formed on the array substrate 10, the array substrate 10 includes a metal layer, and the voltage signal line 30 can be formed on the metal layer. In some embodiments, the metal layer is a composite structure to further reduce the resistivity of the voltage signal line 30 on the metal layer, thereby reducing power consumption during voltage signal transmission. For example, the metal layer includes a titanium metal layer, an aluminum metal layer, and a titanium metal layer stacked in sequence.

In conjunction with the case where the array substrate 10 includes the source-drain metal layer 126, as shown in FIG. 5 or FIG. 6, the source-drain metal layer 126 can be formed with the voltage signal line 30. In this case, the voltage signal on the source-drain metal layer 126 can be connected to the transfer portion 25 through a via in the planarization layer 127. In this case, the source-drain metal layer 126 can be a composite structure layer to reduce power consumption during voltage signal transmission. For example, the source-drain metal layer 126 includes a titanium metal layer, an aluminum metal layer, and a titanium metal layer stacked in sequence. In addition, the voltage signal line 30 located on the source-drain metal layer 126 can be implemented using SIP technologies.

When the array substrate 10 includes a single source-drain metal layer 126, the source-drain metal layer 126 has the voltage signal line 30; and when the array substrate 10 includes a plurality of source-drain metal layers 126, at least one source-drain metal layer 126 has the voltage signal line 30.

For the case where one of the plurality of source-drain metal layers 126 has the voltage signal line 30, if the voltage signal line 30 is formed on a source-drain metal layer 126, among the plurality of source-drain metal layers 126, close to the base substrate 11, the voltage signal line 30 can be connected to the transfer portion 25 through vias in the interlayer dielectric layer 125 and the planarization layer 127; and if the voltage signal line 30 is formed on a source-drain metal layer 126, among the plurality of source-drain metal layers 126, close to the light-emitting layer 20, the voltage signal line 30 can be connected to the transfer portion 25 through the via in the planarization layer 127.

In the case where at least two of the plurality of source-drain metal layers 126 have voltage signal lines 30, the voltage signal lines 30 on the two source-drain metal layers 126 can be connected to different cathode blocks 231 via different transfer portions 25, or can be connected to the same cathode block 231 via the same transfer portion 25. Furthermore, in the case where voltage signal lines 30 on different layers are connected to the same cathode block 231, the transmission resistance of the voltage signal can be further reduced, thereby reducing power consumption while reducing the voltage drop.

The voltage signal lines 30 included in the at least two source-drain metal layers 126 may extend in the same direction. Alternatively, the voltage signal lines 30 in the at least two source-drain metal layers 126 may extend in different directions. For example, two source-drain metal layers 126 have voltage signal lines 30, and voltage signal lines 30 on the two source-drain metal layers 126 extend in directions perpendicular to each other.

For the transfer portion 25 of the light-emitting layer 20, in combination with the structure of the light-emitting layer 20 described above, the transfer portion 25 includes an anode transfer block 212, or as shown in FIG. 5 or FIG. 6, the transfer portion 25 includes the anode transfer block 212 and a light-emitting transfer block 222.

The anode transfer block 212 is located in the anode layer 21 of the light-emitting layer 20 and is spaced apart from the anode block 211. In this case, the anode transfer block 212 is directly connected to the voltage signal line 30 and the cathode block 231. The light-emitting transfer block 222 is located in the organic light-emitting layer 22 of the light-emitting layer 20 and includes at least one of a hole injection layer, a hole transport layer, an electron blocking layer, a hole blocking layer, an electron transport layer, and an electron injection layer. The connection between the anode transfer block 212 and the cathode block 231 is achieved through the light-emitting transfer block 222. The light-emitting transfer block 222 and the light-emitting functional layer 221 can be distributed at intervals or an integrated structure.

When the transfer portion 25 includes the anode transfer block 212, the anode transfer block 212 is respectively connected to the cathode block 231 and the voltage signal line 30 of the array substrate 10. To ensure the connection between the anode transfer block 212 and the cathode block 231, the plurality of light-emitting functional layers 221 included in the organic light-emitting layer 22 are distributed at intervals, and the pixel definition layer 24 has the transfer opening 242 located outside the pixel opening 241. At least a portion of the anode transfer block 212 is exposed at the transfer opening 242. The cathode block 231 is located outside the light-emitting functional layers 221 and is connected to the exposed portion of the anode transfer block 212 at the transfer opening.

When the transfer portion 25 includes the anode transfer block 212 and the light-emitting transfer block 222, the anode transfer block 212 and the light-emitting transfer block 222 function as a whole to connect the voltage signal line 30 to the cathode block 231. If the light-emitting transfer block 222 and the light-emitting functional layer 221 are an integral structure, leakage current may occur between the anode transfer block 212 and the anode block 211 due to the organic light-emitting layer 22. However, since the resistivity of the organic light-emitting layer 22 in the direction perpendicular to the display panel 100 is more than 20 times that of the anode block 211, and the resistivity of the organic light-emitting layer 22 is even greater within the plane of the display panel 100, the leakage current generated between the anode transfer block 212 and the anode block 211 can be ignored, ensuring the voltage signal loaded on the cathode block 231 by the voltage signal line 30.

If the light-emitting transfer block 222 and the light-emitting functional layer 221 are distributed at intervals, leakage current generated between the anode transfer block 212 and the anode block 211 due to the organic light-emitting layer 22 can be completely avoided. Furthermore, the light-emitting layer 20 further includes a partition portion 223, which is in the same layer as the light-emitting transfer block 222 and is located between the light-emitting functional layer 221 and the light-emitting transfer block 222. That is, as shown in FIG. 5 or FIG. 6, the organic light-emitting layer 22 of the light-emitting layer 20 has a partition portion 223, and the partition portion 223 is located between the light-emitting transfer block 222 and the light-emitting functional layer 221, so that the partition portion 223 effectively blocks the conduction between the light-emitting functional layer 221 and the light-emitting transfer block 222.

Embodiments of the present disclosure further provide a method for manufacturing a display panel, which is used to manufacture the display panel described in the above embodiments. As shown in FIG. 7, the method includes the following steps S110 to S120.

In the step S110, an array substrate is manufactured.

In the step S120, a light-emitting layer is manufactured on a side of the array substrate. The light-emitting layer has a plurality of light-emitting units. The light-emitting unit includes an anode block, a light-emitting functional layer, and a cathode block stacked in sequence in a direction away from the array substrate. The light-emitting layer includes a cathode layer, and the cathode layer includes a plurality of cathode blocks distributed at intervals.

In embodiments of the present disclosure, the occlusion of brightness by the cathode layer in areas outside the light-emitting unit can be reduced through the plurality of cathode blocks distributed at intervals, thereby increasing the brightness of the display panel when displaying the image, and improving the display effect.

In conjunction with the above embodiments, the display panel further includes a voltage signal line. In this case, if the voltage signal line is formed on the cathode layer of the light-emitting layer, the cathode layer of the light-emitting layer manufactured in the step S120 further includes the voltage signal line, and the voltage signal line is connected to the cathode block. In this case, for the specific structure of the array substrate produced manufactured in the step S110, reference may be made to the above embodiments.

If the electrical signal line is formed on the array substrate, the step S110 includes manufacturing an array substrate having a voltage signal line, and the step S120 includes manufacturing, on a side of the array substrate, a light-emitting layer having a transfer portion, the transfer portion being connected to the voltage signal line and the cathode block, respectively. For the specific structures of the array substrate and the light-emitting layer manufactured in the steps S110 and S120, reference may be made to the array substrate and the light-emitting layer described in the above embodiments, which will not be repeated in embodiments of the present disclosure.

The present disclosure further provides a display device, which includes the display panel described in the above embodiments. Thus, by using the display panel described in the above embodiments, the brightness of the image displayed by the display device can be effectively increased, thereby improving the display effect.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A display panel, comprising:
an array substrate; and
a light-emitting layer located on a side of the array substrate and comprising a plurality of light-emitting units, wherein each light-emitting unit comprises an anode block, a light-emitting functional layer and a cathode block stacked in sequence in a direction away from the array substrate;
wherein the light-emitting layer comprises a cathode layer, and the cathode layer comprises a plurality of cathode blocks distributed at intervals.

2. The display panel according to claim 1, wherein the cathode layer comprises a plurality of groups of cathode blocks, and each group of cathode blocks is an integrated structure.

3. The display panel according to claim 2, wherein each group of cathode blocks comprises two cathode blocks.

4. The display panel according to claim 1, wherein the cathode layer further comprises a voltage signal line, and the voltage signal line is connected to the cathode blocks.

5. The display panel according to claim 1, wherein the array substrate comprises a voltage signal line, the light-emitting layer further comprises a transfer portion, and the transfer portion is respectively connected to the voltage signal line and the cathode blocks.

6. The display panel according to claim 5, wherein the array substrate comprises a single source-drain metal layer, and the source-drain metal layer comprises the voltage signal line.

7. The display panel according to claim 5, wherein the array substrate comprises a plurality of source-drain metal layers, and at least one of the source-drain metal layers comprises the voltage signal line.

8. The display panel according to claim 7, wherein at least two of the plurality of source-drain metal layers comprise voltage signal lines, and the voltage signal lines of the at least two source-drain metal layers are extended in different directions.

9. The display panel according to claim 6, wherein the source-drain metal layer is a composite structure layer.

10. The display panel according to claim 9, wherein the source-drain metal layer comprises a titanium metal layer, an aluminum metal layer, and a titanium metal layer stacked in sequence.

11. The display panel according to claim 5, wherein the transfer portion comprises an anode transfer block and a light-emitting transfer block, the anode transfer block and the anode block are in the same layer and are distributed at intervals, the light-emitting transfer block is in the same layer as the light-emitting functional layer, and the light-emitting transfer block comprises at least one of a hole injection layer, a hole transport layer, an electron blocking layer, a hole blocking layer, an electron transport layer and an electron injection layer.

12. The display panel according to claim 11, wherein the light-emitting transfer block and the light-emitting functional layer are distributed at intervals.

13. The display panel according to claim 12, wherein the light-emitting layer further comprises a partition portion, and the partition portion is in the same layer as the light-emitting transfer block and is located between the light-emitting functional layer and the light-emitting transfer block.

14. A method for manufacturing a display panel, comprising:
manufacturing an array substrate; and
manufacturing a light-emitting layer on a side of the array substrate, wherein the light-emitting layer comprises a plurality of light-emitting units, each light-emitting unit comprises an anode block, a light-emitting functional layer and a cathode block stacked in sequence in a direction away from the array substrate, the light-emitting layer comprises a cathode layer, and the cathode layer comprises a plurality of cathode blocks distributed at intervals.

15. The method according to claim 14, wherein the cathode layer further comprises a voltage signal line, and the voltage signal line is connected to the cathode blocks.

16. The method according to claim 14, wherein manufacturing the array substrate comprises: manufacturing the array substrate comprising a voltage signal line; and
manufacturing the light-emitting layer on the side of the array substrate comprises: manufacturing, on the side of the array substrate, the light-emitting layer comprising a transfer portion, wherein the transfer portion is respectively connected to the voltage signal line and the cathode blocks.

17. A display device, comprising a display panel, wherein the display panel comprises:
an array substrate; and
a light-emitting layer located on a side of the array substrate and comprising a plurality of light-emitting units, wherein each light-emitting unit comprises an anode block, a light-emitting functional layer and a cathode block stacked in sequence in a direction away from the array substrate:
wherein the light-emitting layer comprises a cathode layer, and the cathode layer comprises a plurality of cathode blocks distributed at intervals.

18. The display device according to claim 17, wherein the cathode layer comprises a plurality of groups of cathode blocks, and each group of cathode blocks is an integrated structure.

19. The display device according to claim 18, wherein each group of cathode blocks comprises two cathode blocks.

20. The display device according to claim 17, wherein the cathode layer further comprises a voltage signal line, and the voltage signal line is connected to the cathode blocks.
